(19) United States
(12) Patent Application Publication
(10) Pub. No.: US 2026/0066652 A1
(43) Pub. Date: Mar. 5, 2026

(54) LITHIUM BATTERY EMERGENCY JUMP STARTER

(71) Applicant: Ningbo Chiyue Electronics Co., Ltd, Yuyao (CN)

(72) Inventors: SENLIAO LOU, Yuyao (CN); HONGLIANG YANG, Yuyao (CN)

(21) Appl. No.: 18/822,360

(22) Filed: Sep. 2, 2024

(51) Int. Cl. H02J 1/10; F21V 23/04; F21V 33/00; F21Y 115/10; G01R 31/378; G01R 31/3835; H01M 10/052; H01M 10/42; H01M 10/46; H01M 10/48; H02J 7/00

(52) U.S. Cl. CPC H02J 1/122; F21V 23/04; F21V 33/0084; G01R 31/378; G01R 31/3835; H01M 10/052; H01M 10/4264; H01M 10/46; H01M 10/482; H01M 10/486; H02J 7/855; H02J 7/865; H02J 7/977; F21Y 2115/10; H01M 2010/4271; H02J 2207/20

(57) ABSTRACT

The present invention discloses a lithium battery emergency jump starter, comprising a rechargeable lithium battery and a relay controller with a magnetization function. The lithium battery controls output through a switch of a relay with the magnetization function driven by the controller; and when positive and negative poles of the lithium battery emergency jump starter are correctly connected to an automobile, large current can be outputted, and a magnetic field after large current is generated can be optimized for demagnetization. The present invention uses the relay controller with the magnetization function, and a magnetic field after large current is generated can be optimized for demagnetization. A USB socket has automatic insertion and detection functions, and also has circuit design to achieve the functions of zero consumption current, lithium battery bulge detection, three-level temperature detection and protection, etc. to form effective feedback and coping mechanisms.

### TECHNICAL FIELD

The present invention relates to the technical field of discharge equipment, and in particular to a lithium battery emergency jump starter.

### BACKGROUND

Vehicles, yachts, etc. are commonly used transportation means. Storage batteries (mostly 12V lead-acid batteries, but some 24V lead-acid batteries) are allocated inside such transportation means, and serve as the electric output devices of the transportation means to meet basic power demands for use of power plant ignition, radio and illumination lamps. However, it is easy for the transportation means to break down when the storage batteries run out of power after used for a long time or suffer from serious power loss due to low temperature in winter. Thus, it is necessary to electrify the broken-down vehicle to realize the emergency start of the transportation means.

A common way of electrification is to find other vehicles to help electrification, or use an emergency jump starter to help to start the transportation means. For convenience, the simplest and most efficient way is to electrify the transportation means with the emergency jump starter. During operation, positive and negative clips on the emergency jump starter are correspondingly clamped to the positions of the positive and negative poles of the storage batteries of the transportation means, and then the vehicle is started to complete the operation of starting by electrification.

Optimization design of the emergency jump starter is a very meaningful job. In addition to meeting the need of electrification, the emergency jump starter should also consider possible or easily generated own defects. These defects are the direction of product optimization, and these defects affect the convenience and safety of the use of the emergency jump starter. These defects comprise:
(1) When the emergency jump starter is started, the positive and negative clips connected to it will generate magnetism after being energized. Once the positive and negative clips are adsorbed together for a long time, it is easy to cause short circuit of the emergency jump starter and damage of an internal circuit of the emergency jump starter.
(2) There is a lack of a protection mechanism for the charging and discharging of the lithium batteries inside the emergency jump starter, and it is easy to damage the emergency jump starter itself.
(3) The emergency jump starter lacks reaction mechanisms under own unfavorable situations, including a coping mechanism under the change of the temperature and the structural form of the lithium batteries. For example, the temperature of the lithium battery is too low and the lithium battery cannot be used, the lithium battery is damaged by ultrahigh temperature, the lithium battery bulges, and the lithium battery burns.

Therefore, the structure is improved and a control system matched with the structure is added in combination with the conventional emergency jump starter, so as to cope with the use under various situations.

### SUMMARY

In view of the defects in the prior art, the purpose of the present invention is to provide a lithium battery emergency jump starter.

The technical solution of the present invention is: a lithium battery emergency jump starter comprises a rechargeable lithium battery and a controller with a magnetization function; the lithium battery controls output through a switch of a relay with the magnetization function driven by the controller; and when positive and negative poles of the lithium battery emergency jump starter are correctly connected to an automobile, large current can be outputted, and a magnetic field after large current is generated can be optimized for demagnetization.

Further, magnetic steel is arranged in the relay.

Further, the controller is connected with an automobile battery voltage detection module, a one-key self-locking 0 power consumption switch module, a battery balance management module, a temperature protection control module, a lithium battery bulge detection module, a start output module, a bidirectional USB module, an LED illuminating lamp, an LED lamp switch module and a power and information display module; the automobile battery voltage detection module is connected with the start output module; the start output module is connected with an insurance module; the insurance module is connected with the bidirectional USB module; the battery balance management module is connected with the one-key self-locking 0 power consumption switch module; and the lithium battery is connected with the battery balance management module, the lithium battery bulge detection module and the temperature protection control module.

Further, the controller has a voltage detection module, and an input end of the voltage detection module is connected with an output end of the automobile battery voltage detection module; the controller has an on-off management module, and an input end of the on-off management module is connected with an output end of the one-key self-locking 0 power consumption switch module; the controller has a charging monitoring module, and the charging monitoring module is connected with the battery balance management module; the controller has a battery low-temperature heating control module and a battery temperature detection module; an output end of the battery low-temperature heating control module is connected with an input end of the temperature protection control module, and an input end of the battery temperature detection module is connected with an output end of the temperature protection control module; the controller has a start control module, and the start control module is connected with the start output module; the controller has a USB control module, a charging control module and an LED illumination lamp control module; the USB control module and the charging control module are connected with the bidirectional USB module; the LED illumination lamp is connected with the bidirectional USB module; an input end of the LED illumination lamp control module is connected with an output end of the LED lamp switch module; the controller has a power and information display control module; and the power and information display control module is connected with the power and information display module.

Further, a plurality of lithium batteries are superimposed inside a lithium battery pack, and the lithium batteries are rechargeable.

Further, the emergency jump starter is closed and disconnected by detecting the voltage of the lithium batteries.

Further, the emergency jump starter comprises a main body and a clamping head electrically connected with the lithium battery pack in the main body; the main body is formed by splicing and fixing an upper cover and a lower cover; a chamber is formed in an interior after the upper cover and the lower cover are spliced; the chamber is fixed with a display screen circuit board at a side that faces the upper cover; the display screen circuit board is provided with a display screen at a side that faces the upper cover; a display screen plastic plate is sleeved outside the display screen; the display screen plastic plate is embedded into a hollow view window of the upper cover, and the display screen circuit board is electrically connected with the lithium battery pack; the lithium battery pack is cladded by an upper shell of the battery pack and a lower shell of the battery pack, and then fixed in the chamber after being cladded; the lithium battery pack is also electrically connected with a USB jack plugging identification circuit board; the USB jack plugging identification circuit board is fixed with a USB connection jack; the USB connection jack faces an outside of the main body; and a relay is also connected between lines for communicating the lithium battery pack and the clamping head.

Further, the clamping head is connected with a wire; one end of the wire enters the main body through left and right side walls of the main body and is connected with the lithium battery pack; a line card is arranged on the wire at a connection with the side walls of the main body; each of the upper cover and the lower cover has a half of a line card slot at the connection; the line card slots on the upper cover and the lower cover just clamp the line card after splicing to achieve fixation; and one side of the line card slots also has a clamping head hanging base.

Further, the clamping head hanging base is made of flame retardant material, and both sides of the clamping head hanging base have a plurality of folds.

Further, the USB connection jack comprises a USB-A jack and a TYPE-C jack.

Further, a top of the main body is also provided with an illumination window, a transparent lamp shade is fixed at the illumination window, and an LED illumination lamp bead circuit board is arranged in the main body.

Further, the battery temperature detection module comprises three temperature detection units; and the temperature detection units are fitted with surfaces of the lithium batteries in the lithium battery pack to perform multi-level detection and protection of the lithium batteries.

Further, the three temperature detection units are a first temperature detection unit, a second temperature detection unit and a third temperature detection unit; when the first temperature detection unit monitors that the temperature of the lithium battery reaches a set value, the battery temperature detection module transmits a signal to the battery balance management module, and the battery balance management module controls and adjusts output power of the lithium battery.

Further, when the first temperature detection unit loses a function due to uncontrollable reasons and the temperature of the lithium battery reaches the set value, the second temperature detection unit starts a monitoring function and feeds back to the battery balance management module.

Further, when the first temperature detection unit and the second temperature detection unit lose functions, the third temperature detection unit begins to work; and once the third temperature detection unit monitors that the temperature of the lithium battery reaches the set value, an output function of the lithium battery emergency jump starter is autonomous to serve as a fuse of the lithium battery emergency jump starter beyond retrieve.

Further, no matter whether the reason why the temperature of the lithium battery reaches the set value is caused by charging or discharging or low temperature, after the battery balance management module receives the information that the temperature reaches the set value fed back by the first temperature detection unit or the second temperature detection unit, the battery balance management module issues an instruction to stop external output or internal input of the lithium battery emergency jump starter; and after the temperature of the lithium battery returns to a normal range, the input or output function is automatically restored.

Further, the battery low-temperature heating control module comprises heating sheets arranged between the surfaces of the lithium batteries, and the heating sheets are connected to positive poles and negative poles of the lithium batteries through the battery balance management module; and the heating sheets are fitted with outer surfaces of the lithium batteries and have flame retardant and insulation characteristics.

Further, after the battery balance management module receives a low-temperature feedback, the battery low-temperature heating control module begins to work, and the heating sheets begin to heat; and the battery low-temperature heating control module stops working when the temperature of the lithium battery reaches a set required value of normal work.

Further, the lithium battery bulge detection module comprises a first metal sheet and a second metal sheet; the first metal sheet is fixed on upper surfaces of the lithium batteries, and the second metal sheet is fixed on inner walls of upper shells of the lithium batteries; after the first metal sheet is in contact with the second metal sheet, the contact is fed back to the battery balance management module; and the battery balance management module determines that the lithium battery is bulged and stops the input or output function of the lithium battery emergency jump starter in time. The stopping behavior is unrecoverable.

Further, the one-key self-locking 0 power consumption switch module automatically closes all input and output functions when the lithium battery emergency jump starter stops working, to achieve 0-current energy consumption.

Further, the one-key self-locking 0 power consumption switch module comprises: a key switch circuit, a shutdown detection circuit, a self-locking loop circuit and a main control module; the key switch circuit comprises a key SW3; the key SW3 is connected with a power positive pole BAT+; the shutdown detection circuit is connected in series between the power positive pole BAT+ and an input end of the main control module through the key SW3; the self-locking loop circuit comprises an MOS tube Q15, a triode Q16, a resistor R84, a resistor R85 and a resistor R87; a collector of the triode Q16 is connected with a gate of the MOS tube Q15 through the resistor R84; a source of the MOS tube Q15 is connected with the power positive pole BAT+; the resistor R85 and the resistor R87 connected in series successively are connected between a drain of the MOS tube Q15 and the triode Q16 to form a self-locking loop; a common end of the resistor R85 and the resistor R87 is connected to an output end of the main control module;

The key SW3 is connected to a base of the triode Q16 through a voltage division resistor; the key SW3 is pressed; the triode Q16 is saturated and switched on, and the MOS tube is switched on to realize startup; the key SW3 is pressed again; the shutdown detection circuit detects a voltage and transmits the voltage to the main control module; the main control module controls the output end to output a low level; the triode Q16 is cut off; and the MOS tube Q15 is disconnected to complete shutdown.

Further, the on-off management module comprises a resistor R78, a resistor R79 and a capacitor C41; the resistor R78 is connected in series between the input end of the main control module and the key SW3; and the resistor R79 and the capacitor C41 are connected in parallel between the input end of the main control module and the ground.

Further, a resistor R83 and a capacitor C43 are connected in parallel between the gate and the source of the MOS tube Q15.

Further, an emitter of the triode Q16 is grounded, and a resistor R88 is connected in series between the base and the emitter of the triode Q16; and a resistor R89 is connected in series between the common end of the resistor R85 and the resistor R87 and the ground.

Further, the drain of the MOS tube Q15 is connected to a VDD end of the main control module through a diode D12, and the drain of the MOS tube Q15 is connected to the power negative pole BAT-through a resistor R8.

Further, the one-key self-locking 0 power consumption switch module is operated by a one-key switch machine, and after shutdown, the loop circuit is disconnected and a post-circuit is completely out of power.

Further, the USB control module can recognize the bidirectional USB module through a TYPE-C interface to charge and discharge the lithium batteries, and can automatically detect and recognize charging or discharging.

Further, the controller is electrically connected with a TYPE-C socket; the controller is connected with a resistor R1 and a resistor R5; the other end of the resistor R1 is connected with VCC; the other end of the resistor R5 is connected with CBSB; a control unit MCU is connected with a capacitor C2, the resistor R8 and a resistor R7; the other ends of the capacitor C2 and the resistor R8 are connected with GND; the other end of the resistor R7 is connected with VBUS; the control unit MCU is electrically connected with a BOOST chip and a BUCK chip; the BOOST chip is electrically connected with a triode Q010; a pin 2 of the BOOST chip is connected with a resistor R2 and then connected with the control unit MCU; a pin 1 of the BOOST chip is connected with a capacitor C23 and a capacitor C27 in parallel; the pin 1 of the BOOST chip is connected with a pin 3 of the triode Q010; a pin 2 of the triode Q010 is connected with a resistor R60, a capacitor C26 and BT+; the other ends of the resistor R60 and the capacitor C26 are connected with a pin 1 of the triode Q010; the pin 1 of the triode Q010 is connected with a resistor R64 and a triode Q14; a base of the triode Q14 is connected with a resistor R76; the other ends of the capacitor C23 and the capacitor C27 are connected with an emitter of the triode Q14; the emitter of the triode Q14 is connected with a resistor R77; the other ends of the resistor R76 and the resistor R77 are connected with DICR; a pin 2 of the BUCK chip is connected with a resistor R10 and a resistor R6 and then connected with the control unit MCU; the resistor R6 is connected with a resistor R11 in series; the resistor R11 is connected with a capacitor C4 in parallel; the resistor R11 and the capacitor C4 are connected with GND; a pin 1 and a pin 3 of the BUCK chip are connected in series through a resistor R3, and the pin 1 is connected with a triode Q09; a pin 3 of the triode Q09 is connected with capacitors C41 and C42; a pin 2 of the triode Q09 is connected with a resistor R026, a capacitor C031 and VBUS; the other ends of the resistor R026 and the capacitor C031 are connected with a pin 1 of the triode Q09; the pin 1 of the triode Q09 is connected with a resistor R81 and a triode Q15; a base of the triode Q15 is connected with a resistor R79; and the other end of the resistor R79 is connected with CH-SW.

Further, a pin 8 of the BOOST chip is connected with an inductor L2; the other end of the inductor L2 is connected with a capacitor C30 and a resistor R57; the other end of the resistor R57 is connected with a capacitor C31, a pin 3 of the BOOST chip, a capacitor C24, a resistor R61 and VBUS; and the other end of the resistor R61 is connected with a capacitor C32.

Further, a pin 7 of the BOOST chip is connected with a capacitor C21, the other end of the capacitor C21 is connected with a resistor R53, the other end of the resistor R53 is connected with a capacitor C22, and the other end of the capacitor C22 is connected with GND.

Further, a pin 9 of the BOOST chip is connected with GND; a pin 6 of the BOOST chip is connected with a capacitor C28; a pin 5 of the BOOST chip is connected with a resistor R63, a resistor R59 and a resistor R67; the other end of the resistor R59 is connected with a capacitor C29; and the other ends of the resistor C29 and the resistor R67 are connected with a capacitor C32.

Further, a pin 6 of the BUCK chip is connected with GND; a pin 4 of the BUCK chip is connected with a capacitor C3; the other end of the capacitor C3 is connected with GND; the pin 2 of the BUCK chip is connected with a resistor R4; the other end of the resistor R4 is connected with a resistor R80; the other end of the resistor R80 is connected with an emitter of the triode Q15 and a resistor R80; and the other end of the resistor R80 is connected with the base of the triode Q15.

Further, a pin 1 of the BUCK chip is connected with an inductor L1; the other end of the inductor L1 is connected with a diode D1 and a rectifier triode M4; a pin 4 of the rectifier triode M4 is connected with a pin 5 of the BUCK chip; a pin 1, a pin 2 and a pin 3 of the rectifier triode M4 are connected with a capacitor C1; the other end of the capacitor C1 is connected with an output end of the diode D1; the output end of the diode D1 is connected with a capacitor C40, a resistor R13 and a triode Q11; the other ends of the capacitor C40 and the resistor R13 and a base of the triode Q11 are connected with a resistor R72 and a triode Q13; an emitter of the triode Q13 is connected with GND; a base of the triode Q13 is connected with a resistor R74 and a resistor R73; and the other end of the resistor R73 is connected with VIN.

Further, the pin 2 of the BUCK chip is connected with a resistor R9, the other end of the resistor R9 is connected with a diode D3, and an input end of the diode D3 is connected with DICR.

Further, the lithium battery emergency jump starter can recognize a disconnected state of the pin when a male connector is not inserted, to complete the plug and pull detection of the male connector of the TYPE-C jack, thereby avoiding the waste of battery energy caused by a reactive working state of a product control circuit during empty plugging of a USB without load.

Further, the lithium battery emergency jump starter is connected with a delayer, and the delayer is communicated with a wire in which the clamping head is located, and communicated with the battery balance management module; the delayer is used for recognizing the voltage of an electrified vehicle; when the clamping head is correctly connected with outside, the delayer releases large-current output after delay, and when the clamping head is wrongly connected with the outside, the lithium battery emergency jump starter does not work.

Further, the delayer comprises a chip, a triode and a resistor.

Further, when the delayer works in delay, a buzzer on a control board generates a prompt tone.

Further, once a delay deadline of the delayer passes, the relay is automatically closed, and large current is outputted; and after the clamping head is disconnected from the outside, an output function of the relay is automatically closed.

Further, when the delayer works, a starting state of the externally connected vehicle is detected in real time; when the voltage generated after the externally connected vehicle is started is greater than the internal voltage of the lithium battery emergency jump starter, the delayer feeds back information to the battery balance management module, and the battery balance management module controls the relay to disconnect the relay to stop large-flow output.

Further, the battery balance management module controls the opening and closing mode of the relay by intermittent opening and closing.

The present invention has the following beneficial effects: the relay controller with the magnetization function is used, and a magnetic field after large current is generated can be optimized for demagnetization. The USB socket has automatic insertion and detection functions, and also has circuit design to achieve the functions of zero consumption current, lithium battery bulge detection, three-level temperature detection and protection, etc. The lithium battery emergency jump starter can cope with various conditions that can be encountered during use, and form setting or detection for various conditions to form effective feedback and coping mechanisms.

### BRIEF DESCRIPTION OF DRAWINGS

FIG. 1 is a system block diagram of the present invention;

FIG. 2A-1 is a partial circuit diagram of a controller of the present invention;

FIG. 2A-2 is a partial circuit diagram of a controller of the present invention;

FIG. 2A-3 is a partial circuit diagram of a controller of the present invention;

FIG. 2A-4 is a partial circuit diagram of a controller of the present invention;

FIG. 3 is a circuit diagram of an LED illumination lamp of the present invention;

FIG. 4 is a circuit diagram of an LED lamp switch module of the present invention;

FIG. 5 is a circuit diagram of a battery temperature detection module of the present invention;

FIG. 6 is a circuit diagram of a buzzer of the present invention;

FIG. 7 is a circuit diagram of a power and information display module of the present invention;

FIG. 8 is a circuit diagram of a charging control module of the present invention;

FIG. 9 is a circuit diagram of an automobile battery voltage detection module of the present invention;

FIG. 10 is a circuit diagram of a lithium battery bulge detection module of the present invention;

FIG. 11 is a circuit diagram of a one-key self-locking 0 power consumption switch module of the present invention;

FIG. 12A-1 is a partial circuit diagram of a bidirectional USB module and a USB control module of the present invention;

FIG. 12A-2 is a partial circuit diagram of a bidirectional USB module and a USB control module of the present invention;

FIG. 13 is a circuit diagram of a charging control module of the present invention;

FIG. 14A-1 is a partial circuit diagram of a battery balance management module of the present invention;

FIG. 14A-2 is a partial circuit diagram of a battery balance management module of the present invention;

FIG. 15 is a circuit diagram of a start output module of the present invention;

FIG. 16 is a circuit diagram of a battery low-temperature heating control module of the present invention;

FIG. 17 is an overall structural schematic diagram of the present invention;

FIG. 18 is an exploded schematic diagram of the present invention.

As shown in the drawings: 1—main body, 101—upper cover; 102—lower cover; 103—line card slot; 104—clamping head hanging base; 2—lithium battery pack; 3—clamping head; 4—display screen circuit board; 5—display screen; 6—display screen plastic plate; 7—upper shell of battery pack; 8—lower shell of battery pack; 9—USB jack plugging identification circuit board; 901—USB connection jack; 9011—USB-A jack; 9012—TYPE-C jack; 10—relay; 11—wire; 12—transparent lamp shade; 13—automobile battery voltage detection module; 14—one-key self-locking 0 power consumption switch module; 15—battery balance management module; 16—temperature protection control module; 17—lithium battery bulge detection module; 18—start output module; 19—bidirectional USB module; 20—LED illumination lamp; 21—LED lamp switch module; 22—power and information display module; 23—insurance module; 24—voltage detection control module; 25—on-off management module; 26—charging monitoring module; 27—battery low-temperature heating control module; 28—battery temperature detection module; 29—start control module; 30—USB control module; 31—charging control module; 32—LED illumination lamp control module; 33—power and information display control module; 34—lithium battery; 35—controller; 36—bulge detection control module.

### DETAILED DESCRIPTION OF THE EMBODIMENTS

In order to understand the technical solution of the present invention more intuitively and completely, the non-restrictive features are described as follows in combination with the drawings of the present invention:

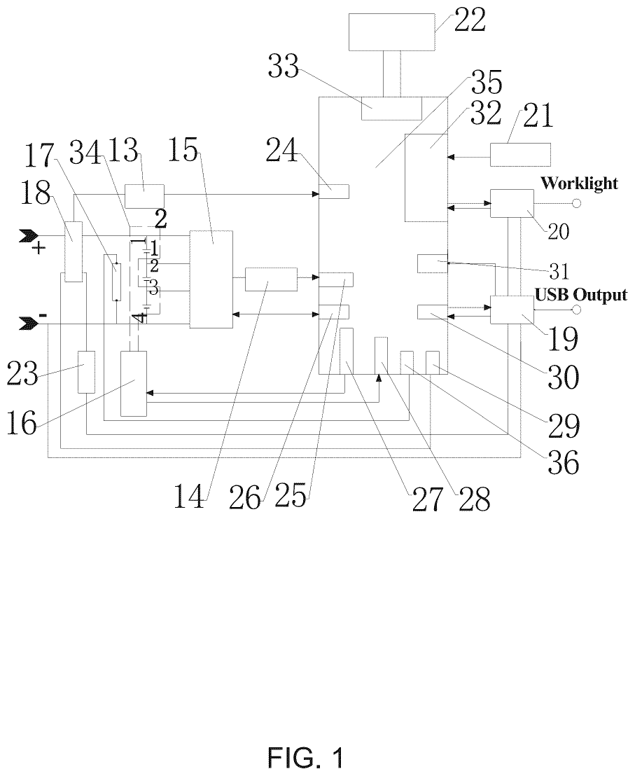

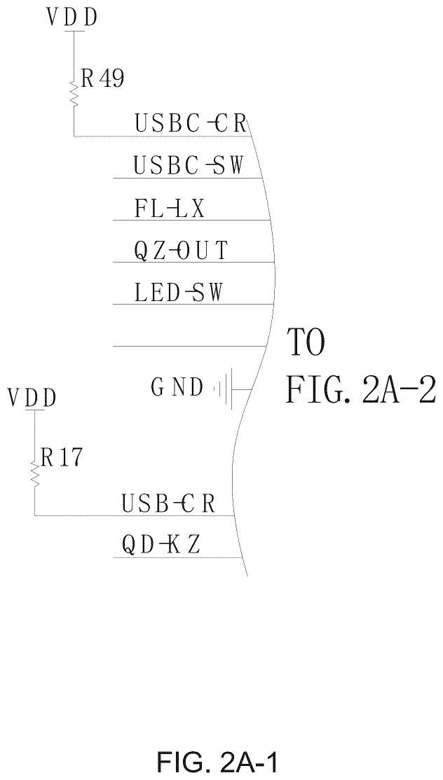

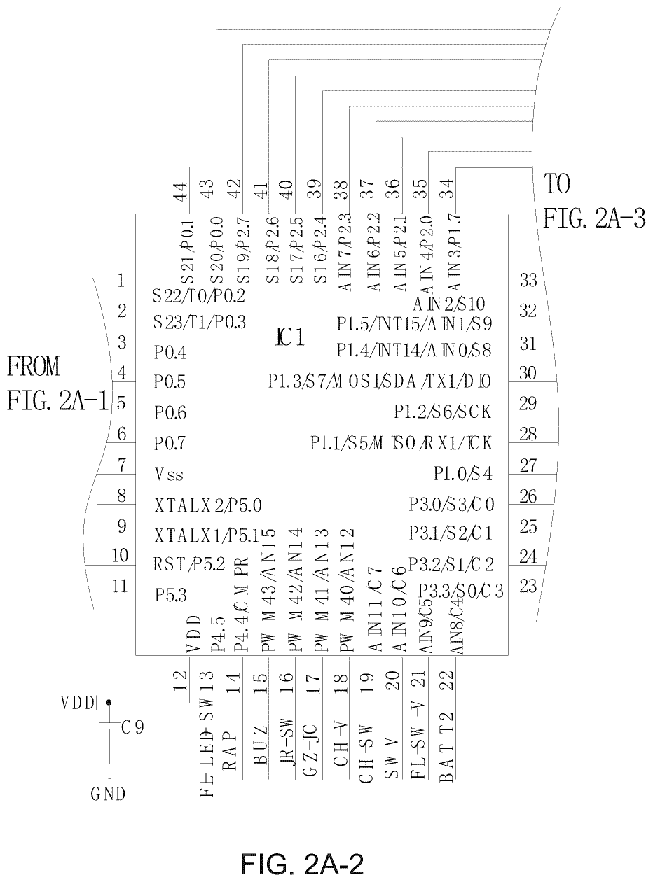

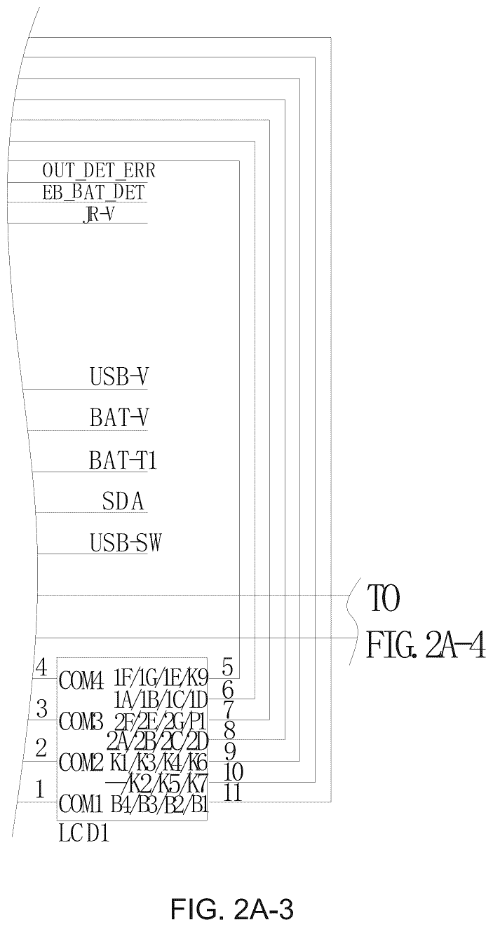

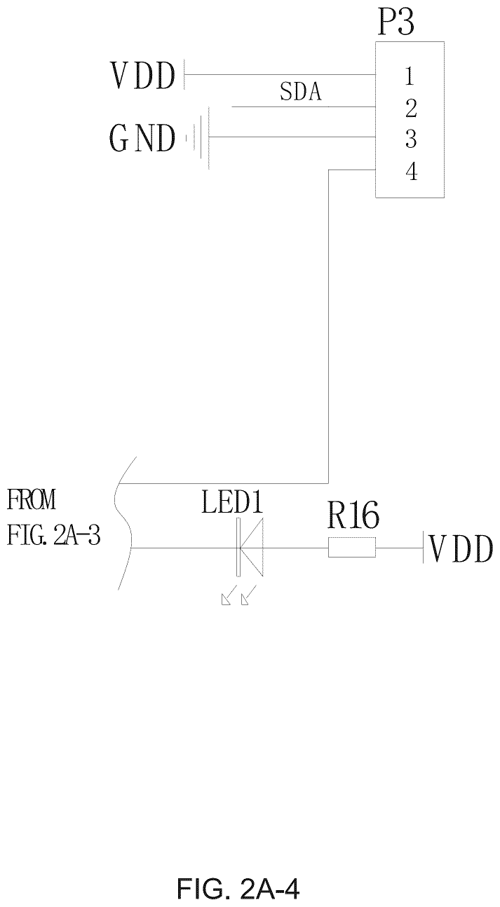

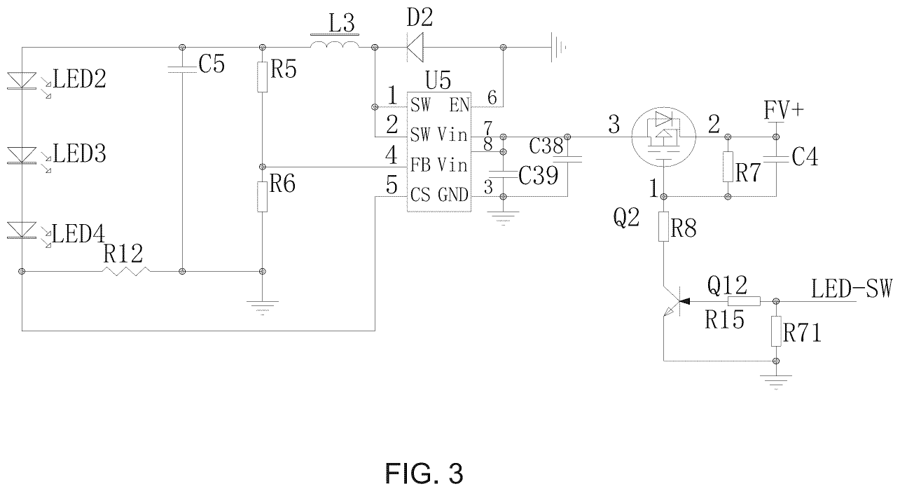

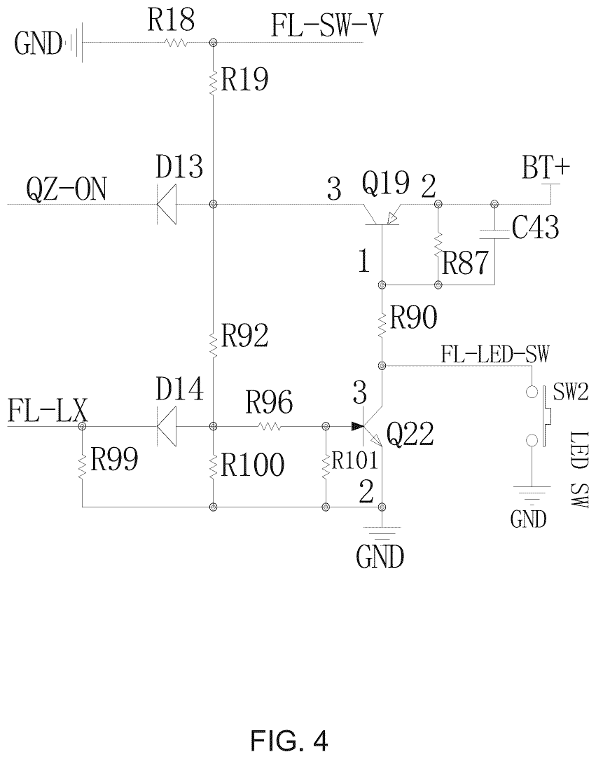

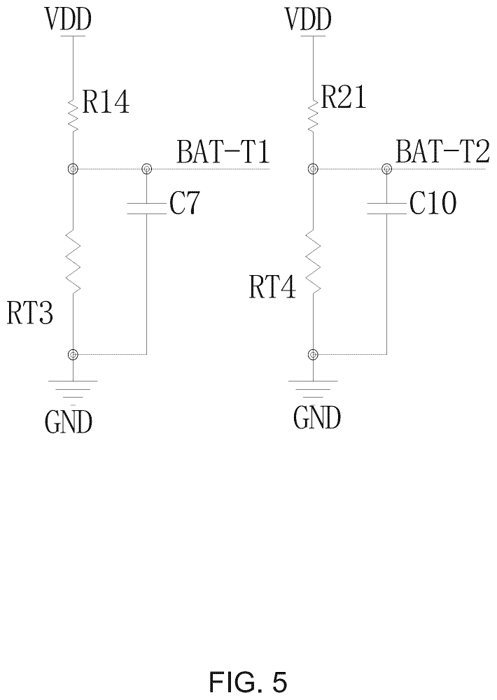

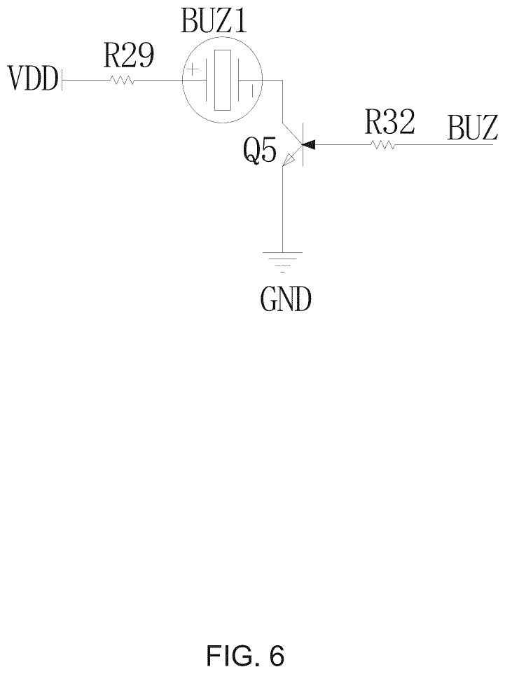

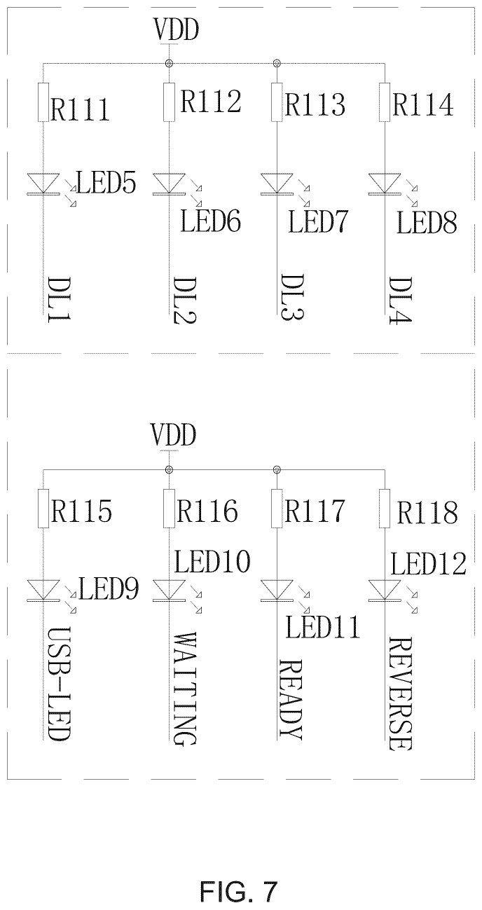

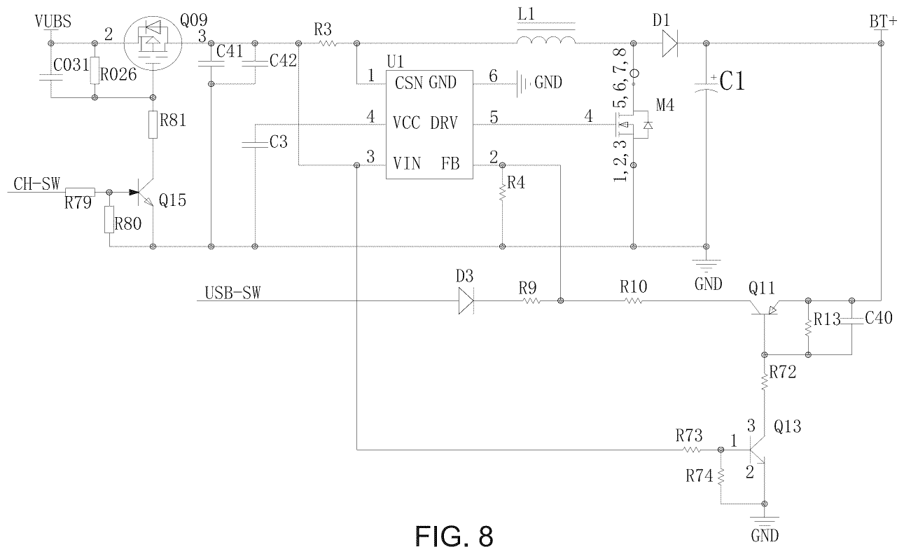

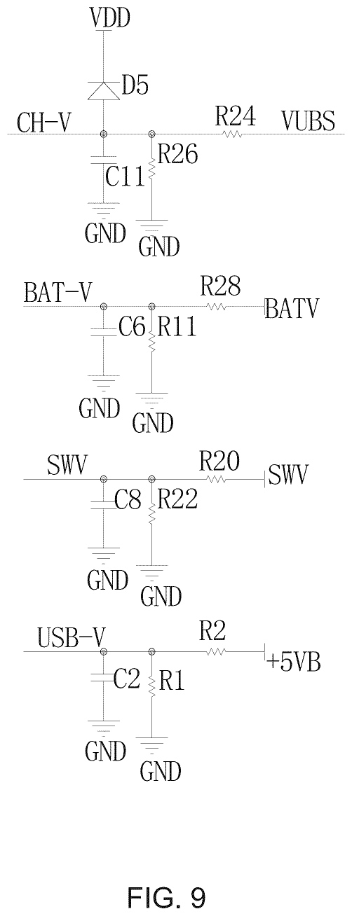

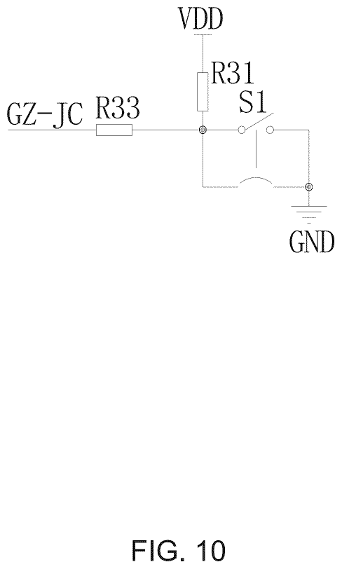

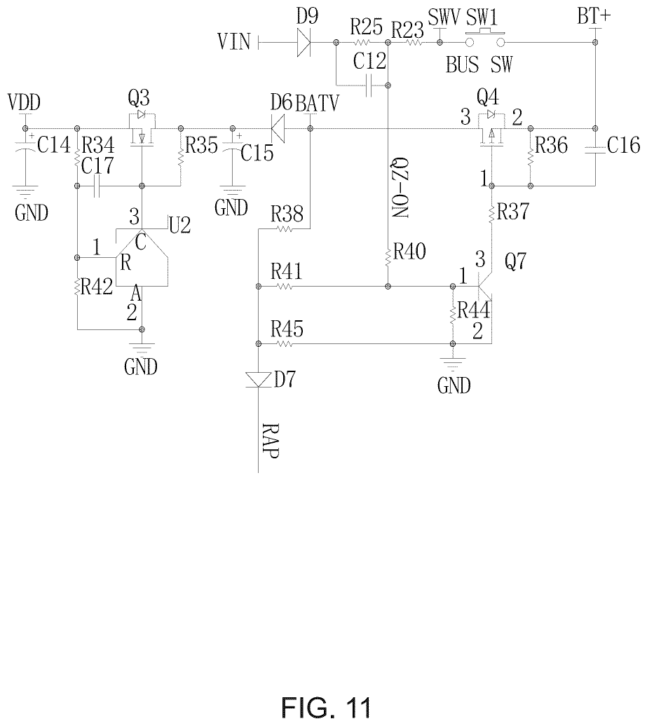

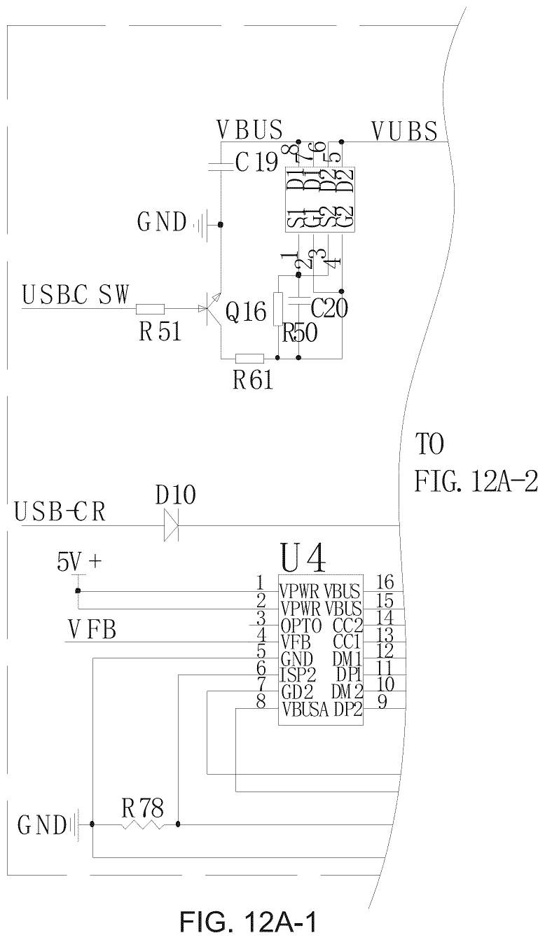

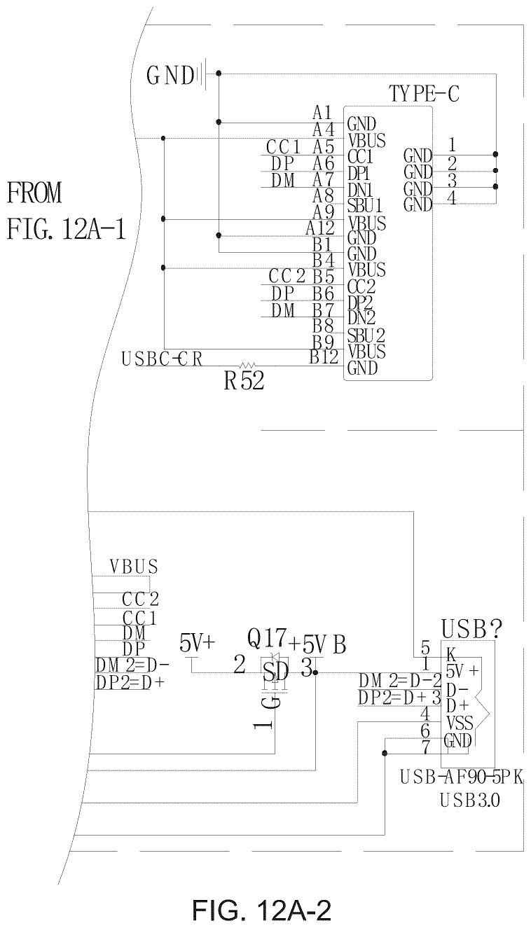

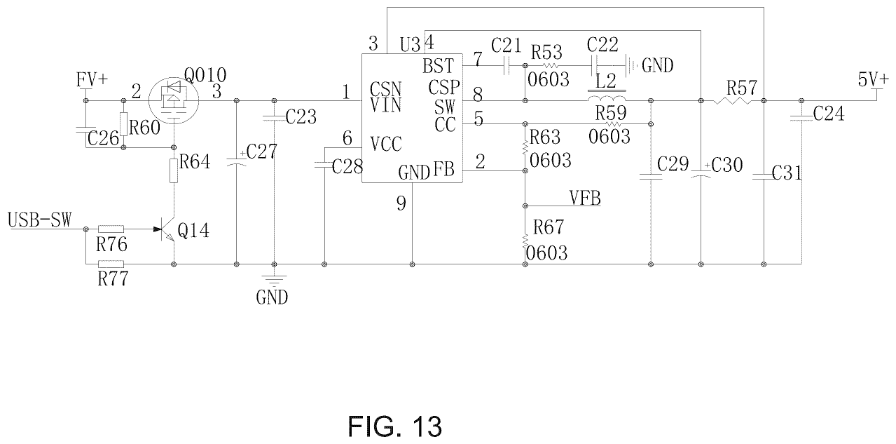

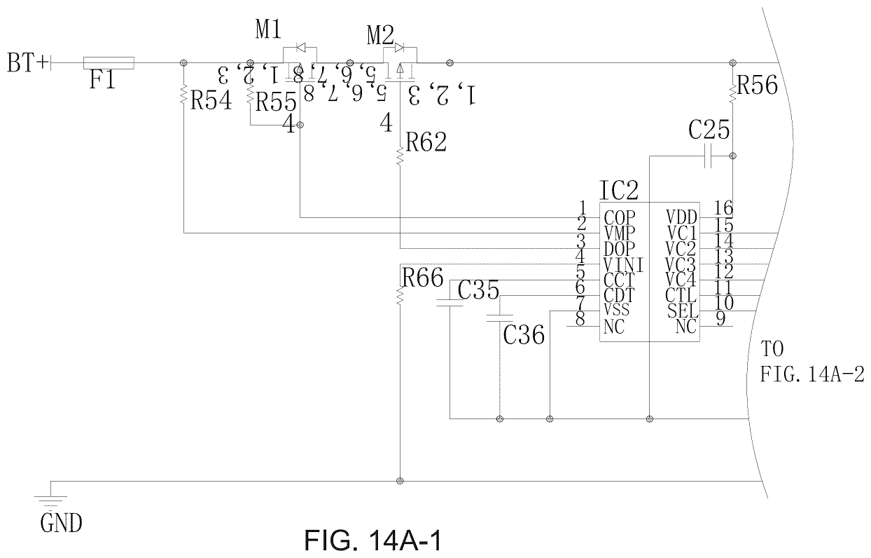

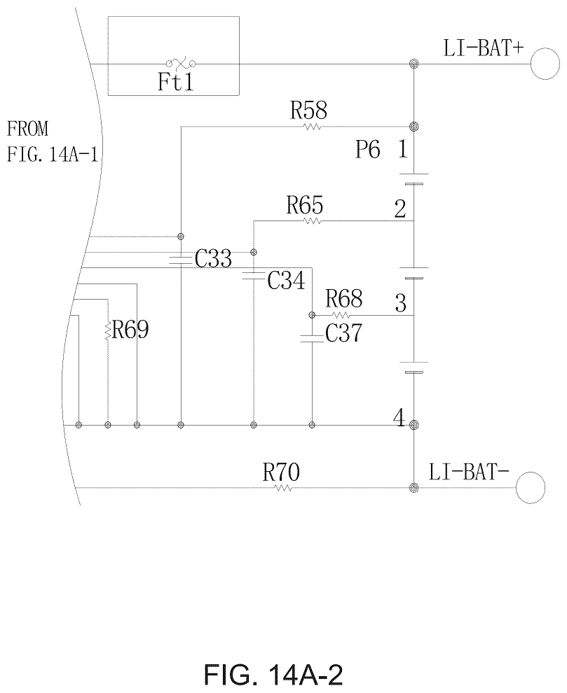

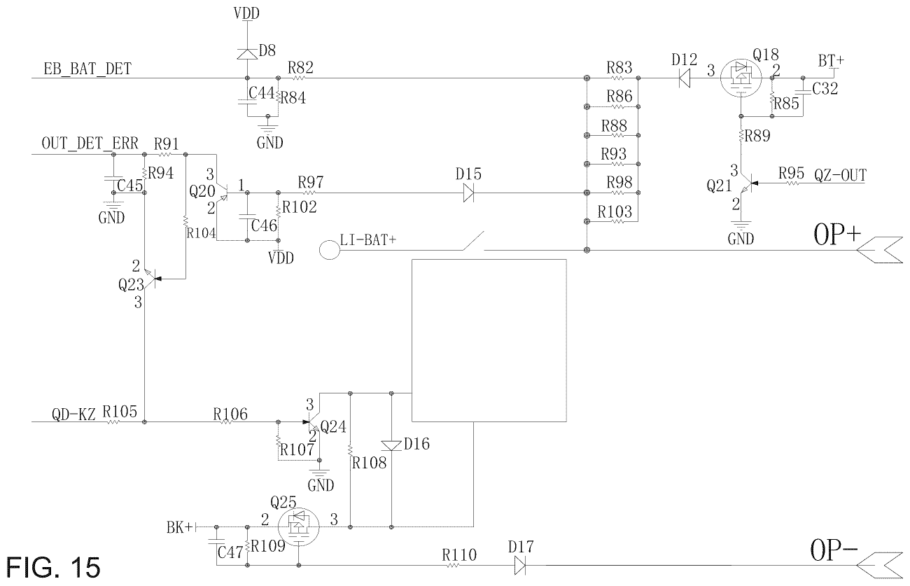

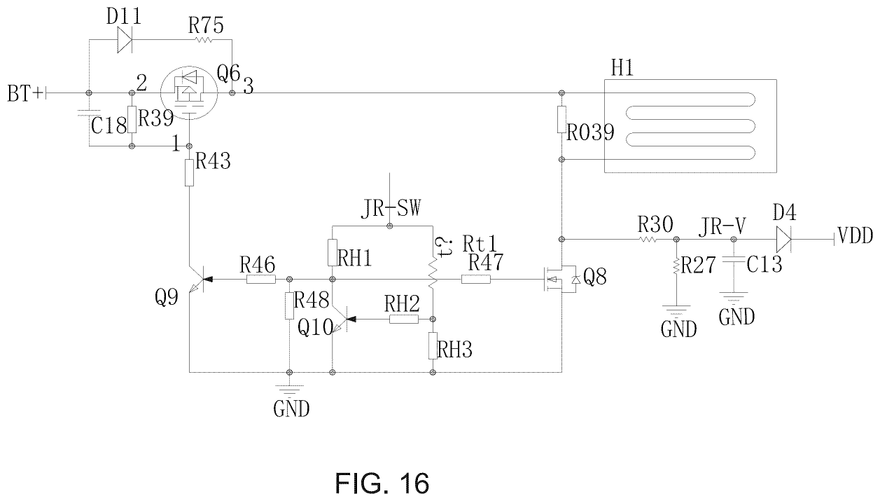

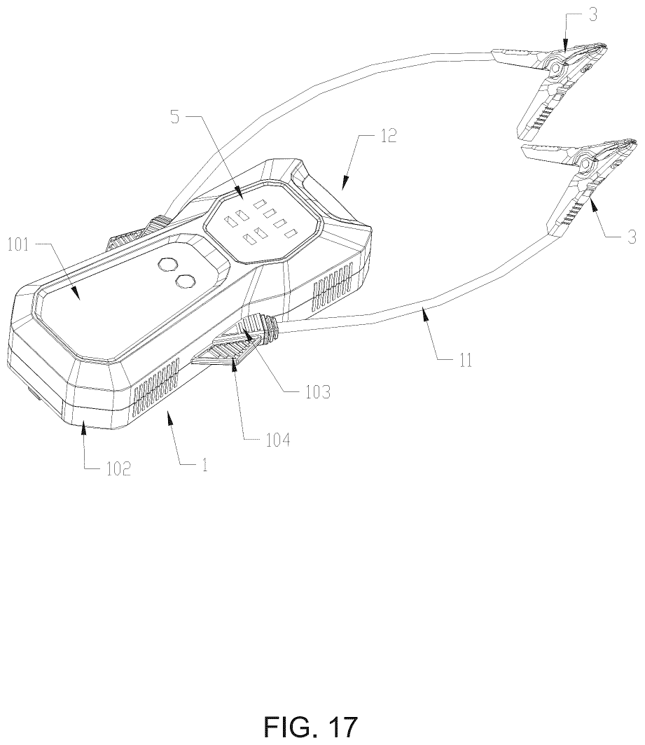

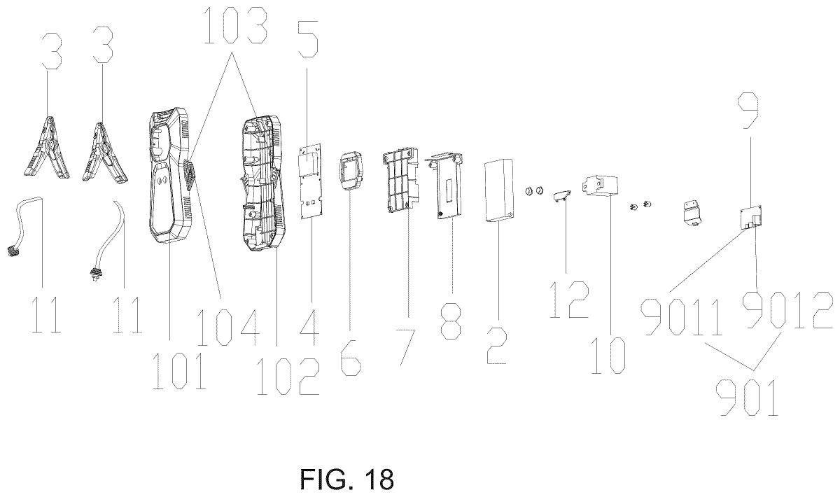

As shown in FIG. 1 to FIG. 18, a lithium battery emergency jump starter comprises a rechargeable lithium battery 34 and a controller 35 with a magnetization function; the lithium battery 34 controls output through a switch of a relay 10 with the magnetization function driven by the controller 35; and when positive and negative poles of the lithium battery emergency jump starter are correctly connected to an automobile, large current can be outputted, and a magnetic field after large current is generated can be optimized for demagnetization. Magnetic steel is arranged in the relay 10.

The controller 35 is connected with an automobile battery voltage detection module 2413, a one-key self-locking 0 power consumption switch module 14, a battery balance management module 15, a temperature protection control module 16, a lithium battery bulge detection module 17, a start output module 18, a bidirectional USB module 19, an LED illuminating lamp 20, an LED lamp switch module 21 and a power and information display module 22; the automobile battery voltage detection module 13 is connected with the start output module 18; the start output module 18 is connected with an insurance module 23; the insurance module 23 is connected with the bidirectional USB module 19; the battery balance management module 15 is connected with the one-key self-locking 0 power consumption switch module 14; and the lithium battery 34 is connected with the battery balance management module 15, the lithium battery bulge detection module 17 and the temperature protection control module 16.

The controller 35 has a voltage control detection module 24, and an input end of the voltage control detection module 24 is connected with an output end of the automobile battery voltage detection module 13; the controller 35 has an on-off management module 25, and an input end of the on-off management module 25 is connected with an output end of the one-key self-locking 0 power consumption switch module 14; the controller 35 has a charging monitoring module 26, and the charging monitoring module 26 is connected with the battery balance management module 15; the controller 35 has a battery low-temperature heating control module 27 and a battery temperature detection module 28; an output end of the battery low-temperature heating control module 27 is connected with an input end of the temperature protection control module 16, and an input end of the battery temperature detection module 28 is connected with an output end of the temperature protection control module 16; the controller 35 has a start control module 29, and the start control module 29 is connected with the start output module 18; the controller 35 has a USB control module 30, a charging control module 31 and an LED illumination lamp control module 32; the USB control module 30 and the charging control module 31 are connected with the bidirectional USB module 19; the LED illumination lamp 20 is connected with the bidirectional USB module 19; an input end of the LED illumination lamp control module 32 is connected with an output end of the LED lamp switch module 21; the controller 35 has a power and information display control module 33; and the power and information display control module 33 is connected with the power and information display module 22; and the controller 35 has a bulge detection control module 36, and the bulge detection control module 36 is connected with the lithium battery bulge detection module 17.

A plurality of lithium batteries are superimposed inside a lithium battery pack 2, and the lithium batteries are rechargeable.

The emergency jump starter is closed and disconnected by detecting the voltage of the lithium batteries 34.

The emergency jump starter comprises a main body 1 and a clamping head 3 electrically connected with the lithium battery pack 2 in the main body 1; the main body 1 is formed by splicing and fixing an upper cover 101 and a lower cover 102; a chamber is formed in an interior after the upper cover 101 and the lower cover 102 are spliced; the chamber is fixed with a display screen circuit board 4 at a side that faces the upper cover 101; the display screen circuit board 4 is provided with a display screen 5 at a side that faces the upper cover 101; a display screen plastic plate 6 is sleeved outside the display screen 5; the display screen plastic plate 6 is embedded into a hollow view window of the upper cover 101, and the display screen circuit board 4 is electrically connected with the lithium battery pack 2; the lithium battery pack 2 is cladded by an upper shell 7 of the battery pack and a lower shell 8 of the battery pack, and then fixed in the chamber after being cladded; the lithium battery pack 2 is also electrically connected with a USB jack plugging identification circuit board 9; the USB jack plugging identification circuit board 9 is fixed with a USB connection jack 901; the USB connection jack 901 faces an outside of the main body 1; and a relay 10 is also connected between lines for communicating the lithium battery pack 2 and the clamping head 3.

The clamping head 3 is connected with a wire 11; one end of the wire 11 enters the main body 1 through left and right side walls of the main body 1 and is connected with the lithium battery pack 2; a line card is arranged on the wire 11 at a connection with the side walls of the main body 1; each of the upper cover 101 and the lower cover 102 has a half of a line card slot 103 at the connection; the line card slots 103 on the upper cover 101 and the lower cover 102 just clamp the line card after splicing to achieve fixation; and one side of the line card slots 103 also has a clamping head hanging base 104.

The clamping head hanging base 104 is made of flame retardant material, and both sides of the clamping head hanging base 104 have a plurality of folds.

The USB connection jack 901 comprises a USB-A jack 9011 and a TYPE-C jack 9012.

A top of the main body 1 is also provided with an illumination window, a transparent lamp shade 12 is fixed at the illumination window, and an LED illumination lamp bead circuit board is arranged in the main body 1.

The battery temperature detection module 28 comprises three temperature detection units; and the temperature detection units are fitted with surfaces of the lithium batteries in the lithium battery pack 2 to perform multi-level detection and protection of the lithium batteries.

The three temperature detection units are a first temperature detection unit, a second temperature detection unit and a third temperature detection unit; when the first temperature detection unit monitors that the temperature of the lithium battery reaches a set value, the battery temperature detection module 28 transmits a signal to the battery balance management module 15, and the battery balance management module 15 controls and adjusts output power of the lithium battery.

When the first temperature detection unit loses a function due to uncontrollable reasons and the temperature of the lithium battery reaches the set value, the second temperature detection unit starts a monitoring function and feeds back to the battery balance management module 15.

When the first temperature detection unit and the second temperature detection unit lose functions, the third temperature detection unit begins to work; and once the third temperature detection unit monitors that the temperature of the lithium battery reaches the set value, an output function of the lithium battery emergency jump starter is autonomous to serve as a fuse of the lithium battery emergency jump starter beyond retrieve.

No matter whether the reason why the temperature of the lithium battery reaches the set value is caused by charging or discharging or low temperature, after the battery balance management module 15 receives the information that the temperature reaches the set value fed back by the first temperature detection unit or the second temperature detection unit, the battery balance management module issues an instruction to stop external output or internal input of the lithium battery emergency jump starter; and after the temperature of the lithium battery returns to a normal range, the input or output function is automatically restored.

The battery low-temperature heating control module 27 comprises heating sheets arranged between the surfaces of the lithium batteries, and the heating sheets are connected to positive poles and negative poles of the lithium batteries through the battery balance management module 15; and the heating sheets are fitted with outer surfaces of the lithium batteries and have flame retardant and insulation characteristics.

After the battery balance management module 15 receives a low-temperature feedback, the battery low-temperature heating control module 27 begins to work, and the heating sheets begin to heat; and the battery low-temperature heating control module 27 stops working when the temperature of the lithium battery reaches a set required value of normal work.

The lithium battery bulge detection module 17 comprises a first metal sheet and a second metal sheet; the first metal sheet is fixed on upper surfaces of the lithium batteries, and the second metal sheet is fixed on inner walls of upper shells of the lithium batteries; after the first metal sheet is in contact with the second metal sheet, the contact is fed back to the battery balance management module 15; and the battery balance management module 15 determines that the lithium battery is bulged and stops the input or output function of the lithium battery emergency jump starter in time. The stopping behavior is unrecoverable.

The one-key self-locking 0 power consumption switch module 14 automatically closes all input and output functions when the lithium battery emergency jump starter stops working, to achieve 0-current energy consumption.

The one-key self-locking 0 power consumption switch module 14 comprises: a key switch circuit, a shutdown detection circuit, a self-locking loop circuit and a main control module; the key switch circuit comprises a key SW3; the key SW3 is connected with a power positive pole BAT+; the shutdown detection circuit is connected in series between the power positive pole BAT+ and an input end of the main control module through the key SW3; the self-locking loop circuit comprises an MOS tube Q15, a triode Q16, a resistor R84, a resistor R85 and a resistor R87; a collector of the triode Q16 is connected with a gate of the MOS tube Q15 through the resistor R84; a source of the MOS tube Q15 is connected with the power positive pole BAT+; the resistor R85 and the resistor R87 connected in series successively are connected between a drain of the MOS tube Q15 and the triode Q16 to form a self-locking loop; a common end of the resistor R85 and the resistor R87 is connected to an output end of the main control module;

The key SW3 is connected to a base of the triode Q16 through a voltage division resistor; the key SW3 is pressed; the triode Q16 is saturated and switched on, and the MOS tube is switched on to realize startup; the key SW3 is pressed again; the shutdown detection circuit detects a voltage and transmits the voltage to the main control module; the main control module controls the output end to output a low level; the triode Q16 is cut off; and the MOS tube Q15 is disconnected to complete shutdown.

The on-off management module 25 comprises a resistor R78, a resistor R79 and a capacitor C41; the resistor R78 is connected in series between the input end of the main control module and the key SW3; and the resistor R79 and the capacitor C41 are connected in parallel between the input end of the main control module and the ground.

A resistor R83 and a capacitor C43 are connected in parallel between the gate and the source of the MOS tube Q15.

An emitter of the triode Q16 is grounded, and a resistor R88 is connected in series between the base and the emitter of the triode Q16; and a resistor R89 is connected in series between the common end of the resistor R85 and the resistor R87 and the ground.

The drain of the MOS tube Q15 is connected to a VDD end of the main control module through a diode D12, and the drain of the MOS tube Q15 is connected to the power negative pole BAT-through a resistor R8.

The one-key self-locking 0 power consumption switch module 14 is operated by a one-key switch machine, and after shutdown, the loop circuit is disconnected and a post-circuit is completely out of power.

The USB control module 30 can recognize the bidirectional USB module 19 through a TYPE-C interface to charge and discharge the lithium batteries, and can automatically detect and recognize charging or discharging.

The controller is electrically connected with a TYPE-C socket; the controller is connected with a resistor R1 and a resistor R5; the other end of the resistor R1 is connected with VCC; the other end of the resistor R5 is connected with CBSB; a control unit MCU is connected with a capacitor C2, the resistor R8 and a resistor R7; the other ends of the capacitor C2 and the resistor R8 are connected with GND; the other end of the resistor R7 is connected with VBUS; the control unit MCU is electrically connected with a BOOST chip and a BUCK chip; the BOOST chip is electrically connected with a triode Q010; a pin 2 of the BOOST chip is connected with a resistor R2 and then connected with the control unit MCU; a pin 1 of the BOOST chip is connected with a capacitor C23 and a capacitor C27 in parallel; the pin 1 of the BOOST chip is connected with a pin 3 of the triode Q010; a pin 2 of the triode Q010 is connected with a resistor R60, a capacitor C26 and BT+; the other ends of the resistor R60 and the capacitor C26 are connected with a pin 1 of the triode Q010; the pin 1 of the triode Q010 is connected with a resistor R64 and a triode Q14; a base of the triode Q14 is connected with a resistor R76; the other ends of the capacitor C23 and the capacitor C27 are connected with an emitter of the triode Q14; the emitter of the triode Q14 is connected with a resistor R77; the other ends of the resistor R76 and the resistor R77 are connected with DICR; a pin 2 of the BUCK chip is connected with a resistor R10 and a resistor R6 and then connected with the control unit MCU; the resistor R6 is connected with a resistor R11 in series; the resistor R11 is connected with a capacitor C4 in parallel; the resistor R11 and the capacitor C4 are connected with GND; a pin 1 and a pin 3 of the BUCK chip are connected in series through a resistor R3, and the pin 1 is connected with a triode Q09; a pin 3 of the triode Q09 is connected with capacitors C41 and C42; a pin 2 of the triode Q09 is connected with a resistor R026, a capacitor C031 and VBUS; the other ends of the resistor R026 and the capacitor C031 are connected with a pin 1 of the triode Q09; the pin 1 of the triode Q09 is connected with a resistor R81 and a triode Q15; a base of the triode Q15 is connected with a resistor R79; and the other end of the resistor R79 is connected with CH-SW.

A pin 8 of the BOOST chip is connected with an inductor L2; the other end of the inductor L2 is connected with a capacitor C30 and a resistor R57; the other end of the resistor R57 is connected with a capacitor C31, a pin 3 of the BOOST chip, a capacitor C24, a resistor R61 and VBUS; and the other end of the resistor R61 is connected with a capacitor C32.

A pin 7 of the BOOST chip is connected with a capacitor C21, the other end of the capacitor C21 is connected with a resistor R53, the other end of the resistor R53 is connected with a capacitor C22, and the other end of the capacitor C22 is connected with GND.

A pin 9 of the BOOST chip is connected with GND; a pin 6 of the BOOST chip is connected with a capacitor C28; a pin 5 of the BOOST chip is connected with a resistor R63, a resistor R59 and a resistor R67; the other end of the resistor R59 is connected with a capacitor C29; and the other ends of the resistor C29 and the resistor R67 are connected with a capacitor C32.

A pin 6 of the BUCK chip is connected with GND; a pin 4 of the BUCK chip is connected with a capacitor C3; the other end of the capacitor C3 is connected with GND; the pin 2 of the BUCK chip is connected with a resistor R4; the other end of the resistor R4 is connected with a resistor R80; the other end of the resistor R80 is connected with an emitter of the triode Q15 and a resistor R80; and the other end of the resistor R80 is connected with the base of the triode Q15.

A pin 1 of the BUCK chip is connected with an inductor L1; the other end of the inductor L1 is connected with a diode D1 and a rectifier triode M4; a pin 4 of the rectifier triode M4 is connected with a pin 5 of the BUCK chip; a pin 1, a pin 2 and a pin 3 of the rectifier triode M4 are connected with a capacitor C1; the other end of the capacitor C1 is connected with an output end of the diode D1; the output end of the diode D1 is connected with a capacitor C40, a resistor R13 and a triode Q11; the other ends of the capacitor C40 and the resistor R13 and a base of the triode Q11 are connected with a resistor R72 and a triode Q13; an emitter of the triode Q13 is connected with GND; a base of the triode Q13 is connected with a resistor R74 and a resistor R73; and the other end of the resistor R73 is connected with VIN.

The pin 2 of the BUCK chip is connected with a resistor R9, the other end of the resistor R9 is connected with a diode D3, and an input end of the diode D3 is connected with DICR.

The lithium battery emergency jump starter can recognize a disconnected state of the pin when a male connector is not inserted, to complete the plug and pull detection of the male connector of the TYPE-C jack, thereby avoiding the waste of battery energy caused by a reactive working state of a product control circuit during empty plugging of a USB without load.

The lithium battery emergency jump starter is connected with a delayer, and the delayer is communicated with a wire 11 in which the clamping head 3 is located, and communicated with the battery balance management module 15; the delayer is used for recognizing the voltage of an electrified vehicle; when the clamping head 3 is correctly connected with outside, the delayer releases large-current output after delay, and when the clamping head 3 is wrongly connected with the outside, the lithium battery emergency jump starter does not work.

The delayer comprises a chip, a triode and a resistor.

When the delayer works in delay, a buzzer on a control board generates a prompt tone.

Once a delay deadline of the delayer passes, the relay 10 is automatically closed, and large current is outputted; and after the clamping head 3 is disconnected from the outside, an output function of the relay 10 is automatically closed.

When the delayer works, a starting state of the externally connected vehicle is detected in real time; when the voltage generated after the externally connected vehicle is started is greater than the internal voltage of the lithium battery emergency jump starter, the delayer feeds back information to the battery balance management module 15, and the battery balance management module 15 controls the relay 10 to disconnect the relay 10 to stop large-flow output.

The battery balance management module 15 controls the opening and closing mode of the relay 10 by intermittent opening and closing.

The present invention has the controller with the magnetization function, and a magnetic field after large current is generated can be optimized for demagnetization. The USB socket has automatic insertion and detection functions, and also has circuit design to achieve the functions of zero consumption current, lithium battery bulge detection, three-level temperature detection and protection, etc. The lithium battery emergency jump starter can cope with various conditions that can be encountered during use, and form setting or detection for various conditions to form effective feedback and coping mechanisms.

Of course, the above only describes the preferred embodiments of the present invention, and does not limit the scope of the patent of the present invention. All simple modifications and equivalent structural changes made by using the description and schematic content of the present invention shall be included within the protection scope of the patent of the present invention in the same way.

What is claimed is:

1. A lithium battery emergency jump starter, comprising a rechargeable lithium battery and a controller with a magnetization function, wherein the lithium battery controls output through a switch of a relay with the magnetization function driven by the controller; and when positive and negative poles of the lithium battery emergency jump starter are correctly connected to an automobile, large current can be outputted, and a magnetic field after large current is generated can be optimized for demagnetization.

2. The lithium battery emergency jump starter according to claim 1, wherein magnetic steel is arranged in the relay.

3. The lithium battery emergency jump starter according to claim 1, wherein the controller is connected with an automobile battery voltage detection module, a one-key self-locking 0 power consumption switch module, a battery balance management module, a temperature protection control module, a lithium battery bulge detection module, a start output module, a bidirectional USB module, an LED illuminating lamp, an LED lamp switch module and a power and information display module; the automobile battery voltage detection module is connected with the start output module; the start output module is connected with an insurance module; the insurance module is connected with the bidirectional USB module; the battery balance management module is connected with the one-key self-locking 0 power consumption switch module; and the lithium battery is connected with the battery balance management module, the lithium battery bulge detection module and the temperature protection control module.

4. The lithium battery emergency jump starter according to claim 3, wherein the controller has a voltage detection module, and an input end of the voltage detection module is connected with an output end of the automobile battery voltage detection module; the controller has an on-off management module, and an input end of the on-off management module is connected with an output end of the one-key self-locking 0 power consumption switch module; the controller has a charging monitoring module, and the charging monitoring module is connected with the battery balance management module; the controller has a battery low-temperature heating control module and a battery temperature detection module; an output end of the battery low-temperature heating control module is connected with an input end of the temperature protection control module, and an input end of the battery temperature detection module is connected with an output end of the temperature protection control module; the controller has a start control module, and the start control module is connected with the start output module; the controller has a USB control module, a charging control module and an LED illumination lamp control module; the USB control module and the charging control module are connected with the bidirectional USB module; the LED illumination lamp is connected with the bidirectional USB module; an input end of the LED illumination lamp control module is connected with an output end of the LED lamp switch module; the controller has a power and information display control module; and the power and information display control module is connected with the power and information display module.

5. The lithium battery emergency jump starter according to claim 1, wherein a plurality of lithium batteries are superimposed inside a lithium battery pack, and the lithium batteries are rechargeable.

6. The lithium battery emergency jump starter according to claim 1, wherein the emergency jump starter is closed and disconnected by detecting the voltage of the lithium batteries.

7. The lithium battery emergency jump starter according to claim 1, wherein the emergency jump starter comprises a main body and a clamping head electrically connected with the lithium battery pack in the main body; the main body is formed by splicing and fixing an upper cover and a lower cover; a chamber is formed in an interior after the upper cover and the lower cover are spliced; the chamber is fixed with a display screen circuit board at a side that faces the upper cover; the display screen circuit board is provided with a display screen at a side that faces the upper cover; a display screen plastic plate is sleeved outside the display screen; the display screen plastic plate is embedded into a hollow view window of the upper cover, and the display screen circuit board is electrically connected with the lithium battery pack; the lithium battery pack is cladded by an upper shell of the battery pack and a lower shell of the battery pack, and then fixed in the chamber after being cladded; the lithium battery pack is also electrically connected with a USB jack plugging identification circuit board; the USB jack plugging identification circuit board is fixed with a USB connection jack; the USB connection jack faces an outside of the main body; and a relay is also connected between lines for communicating the lithium battery pack and the clamping head.

8. The lithium battery emergency jump starter according to claim 7, wherein the clamping head is connected with a wire; one end of the wire enters the main body through left and right side walls of the main body and is connected with the lithium battery pack; a line card is arranged on the wire at a connection with the side walls of the main body; each of the upper cover and the lower cover has a half of a line card slot at the connection; the line card slots on the upper cover and the lower cover just clamp the line card after splicing to achieve fixation; and one side of the line card slots also has a clamping head hanging base.

9. The lithium battery emergency jump starter according to claim 8, wherein the clamping head hanging base is made of flame retardant material, and both sides of the clamping head hanging base have a plurality of folds.

10. The lithium battery emergency jump starter according to claim 9, wherein the USB connection jack comprises a USB-A jack and a TYPE-C jack.

11. The lithium battery emergency jump starter according to claim 10, wherein a top of the main body is also provided with an illumination window, a transparent lamp shade is fixed at the illumination window, and an LED illumination lamp bead circuit board is arranged in the main body.

12. The lithium battery emergency jump starter according to claim 4, wherein the battery temperature detection module comprises three temperature detection units; and the temperature detection units are fitted with surfaces of the lithium batteries in the lithium battery pack to perform multi-level detection and protection of the lithium batteries.

13. The lithium battery emergency jump starter according to claim 12, wherein the three temperature detection units are a first temperature detection unit, a second temperature detection unit and a third temperature detection unit; when the first temperature detection unit monitors that the temperature of the lithium battery reaches a set value, the battery temperature detection module transmits a signal to the battery balance management module, and the battery balance management module controls and adjusts output power of the lithium battery.

14. The lithium battery emergency jump starter according to claim 13, wherein when the first temperature detection unit loses a function due to uncontrollable reasons and the temperature of the lithium battery reaches the set value, the second temperature detection unit starts a monitoring function and feeds back to the battery balance management module.

15. The lithium battery emergency jump starter according to claim 14, wherein when the first temperature detection unit and the second temperature detection unit lose functions, the third temperature detection unit begins to work; and once the third temperature detection unit monitors that the temperature of the lithium battery reaches the set value, an output function of the lithium battery emergency jump starter is autonomous to serve as a fuse of the lithium battery emergency jump starter beyond retrieve.

16. The lithium battery emergency jump starter according to claim 15, wherein no matter whether the reason why the temperature of the lithium battery reaches the set value is caused by charging or discharging or low temperature, after the battery balance management module receives the information that the temperature reaches the set value fed back by the first temperature detection unit or the second temperature detection unit, the battery balance management module issues an instruction to stop external output or internal input of the lithium battery emergency jump starter; and after the temperature of the lithium battery returns to a normal range, the input or output function is automatically restored.

17. The lithium battery emergency jump starter according to claim 16, wherein the battery low-temperature heating control module comprises heating sheets arranged between the surfaces of the lithium batteries, and the heating sheets are connected to positive poles and negative poles of the lithium batteries through the battery balance management module; and the heating sheets are fitted with outer surfaces of the lithium batteries and have flame retardant and insulation characteristics.

18. The lithium battery emergency jump starter according to claim 17, wherein after the battery balance management module receives a low-temperature feedback, the battery low-temperature heating control module begins to work, and the heating sheets begin to heat; and the battery low-temperature heating control module stops working when the temperature of the lithium battery reaches a set required value of normal work.

19. The lithium battery emergency jump starter according to claim 18, wherein the lithium battery bulge detection module comprises a first metal sheet and a second metal sheet; the first metal sheet is fixed on upper surfaces of the lithium batteries, and the second metal sheet is fixed on inner walls of upper shells of the lithium batteries; after the first metal sheet is in contact with the second metal sheet, the contact is fed back to the battery balance management module; the battery balance management module determines that the lithium battery is bulged and stops the input or output function of the lithium battery emergency jump starter in time; and the stopping behavior is unrecoverable.

20. The lithium battery emergency jump starter according to claim 4, wherein the one-0 key self-locking 0 power consumption switch module automatically closes all input and output functions when the lithium battery emergency jump starter stops working, to achieve 0-current energy consumption.

21. The lithium battery emergency jump starter according to claim 20, wherein the one-key self-locking 0 power consumption switch module comprises: a key switch circuit, a shutdown detection circuit, a self-locking loop circuit and a main control module; the key switch circuit comprises a key SW3; the key SW3 is connected with a power positive pole BAT+; the shutdown detection circuit is connected in series between the power positive pole BAT+ and an input end of the main control module through the key SW3; the self-locking loop circuit comprises an MOS tube Q15, a triode Q16, a resistor R84, a resistor R85 and a resistor R87; a collector of the triode Q16 is connected with a gate of the MOS tube Q15 through the resistor R84; a source of the MOS tube Q15 is connected with the power positive pole BAT+; the resistor R85 and the resistor R87 connected in series successively are connected between a drain of the MOS tube Q15 and the triode Q16 to form a self-locking loop; a common end of the resistor R85 and the resistor R87 is connected to an output end of the main control module;
the key SW3 is connected to a base of the triode Q16 through a voltage division resistor; the key SW3 is pressed; the triode Q16 is saturated and switched on, and the MOS tube is switched on to realize startup; the key SW3 is pressed again; the shutdown detection circuit detects a voltage and transmits the voltage to the main control module; the main control module controls the output end to output a low level; the triode Q16 is cut off; and the MOS tube Q15 is disconnected to complete shutdown.

22. The lithium battery emergency jump starter according to claim 21, wherein the on-off management module comprises a resistor R78, a resistor R79 and a capacitor C41; the resistor R78 is connected in series between the input end of the main control module and the key SW3; and the resistor R79 and the capacitor C41 are connected in parallel between the input end of the main control module and the ground.

23. The lithium battery emergency jump starter according to claim 22, wherein a resistor R83 and a capacitor C43 are connected in parallel between the gate and the source of the MOS tube Q15.

24. The lithium battery emergency jump starter according to claim 23, wherein an emitter of the triode Q16 is grounded, and a resistor R88 is connected in series between the base and the emitter of the triode Q16; and a resistor R89 is connected in series between the common end of the resistor R85 and the resistor R87 and the ground.

25. The lithium battery emergency jump starter according to claim 24, wherein the drain of the MOS tube Q15 is connected to a VDD end of the main control module through a diode D12, and the drain of the MOS tube Q15 is connected to the power negative pole BAT-through a resistor R8.

26. The lithium battery emergency jump starter according to claim 25, wherein the one-key self-locking 0 power consumption switch module is operated by a one-key switch machine, and after shutdown, the loop circuit is disconnected and a post-circuit is completely out of power.

27. The lithium battery emergency jump starter according to claim 4, wherein the USB control module can recognize the bidirectional USB module through a TYPE-C interface to charge and discharge the lithium batteries, and can automatically detect and recognize charging or discharging.

28. The lithium battery emergency jump starter according to claim 27, wherein the controller is electrically connected with a TYPE-C socket; the controller is connected with a resistor R1 and a resistor R5; the other end of the resistor R1 is connected with VCC; the other end of the resistor R5 is connected with CBSB; a control unit MCU is connected with a capacitor C2, the resistor R8 and a resistor R7; the other ends of the capacitor C2 and the resistor R8 are connected with GND; the other end of the resistor R7 is connected with VBUS; the control unit MCU is electrically connected with a BOOST chip and a BUCK chip; the BOOST chip is electrically connected with a triode Q010; a pin 2 of the BOOST chip is connected with a resistor R2 and then connected with the control unit MCU; a pin 1 of the BOOST chip is connected with a capacitor C23 and a capacitor C27 in parallel; the pin 1 of the BOOST chip is connected with a pin 3 of the triode Q010; a pin 2 of the triode Q010 is connected with a resistor R60, a capacitor C26 and BT+; the other ends of the resistor R60 and the capacitor C26 are connected with a pin 1 of the triode Q010; the pin 1 of the triode Q010 is connected with a resistor R64 and a triode Q14; a base of the triode Q14 is connected with a resistor R76; the other ends of the capacitor C23 and the capacitor C27 are connected with an emitter of the triode Q14; the emitter of the triode Q14 is connected with a resistor R77; the other ends of the resistor R76 and the resistor R77 are connected with DICR; a pin 2 of the BUCK chip is connected with a resistor R10 and a resistor R6 and then connected with the control unit MCU; the resistor R6 is connected with a resistor R11 in series; the resistor R11 is connected with a capacitor C4 in parallel; the resistor R11 and the capacitor C4 are connected with GND; a pin 1 and a pin 3 of the BUCK chip are connected in series through a resistor R3, and the pin 1 is connected with a triode Q09; a pin 3 of the triode Q09 is connected with capacitors C41 and C42; a pin 2 of the triode Q09 is connected with a resistor R026, a capacitor C031 and VBUS; the other ends of the resistor R026 and the capacitor C031 are connected with a pin 1 of the triode Q09; the pin 1 of the triode Q09 is connected with a resistor R81 and a triode Q15; a base of the triode Q15 is connected with a resistor R79; and the other end of the resistor R79 is connected with CH-SW.

29. The lithium battery emergency jump starter according to claim 28, wherein a pin 8 of the BOOST chip is connected with an inductor L2; the other end of the inductor L2 is connected with a capacitor C30 and a resistor R57; the other end of the resistor R57 is connected with a capacitor C31, a pin 3 of the BOOST chip, a capacitor C24, a resistor R61 and VBUS; and the other end of the resistor R61 is connected with a capacitor C32.

30. The lithium battery emergency jump starter according to claim 29, wherein a pin 7 of the BOOST chip is connected with a capacitor C21, the other end of the capacitor C21 is connected with a resistor R53, the other end of the resistor R53 is connected with a capacitor C22, and the other end of the capacitor C22 is connected with GND.

31. The lithium battery emergency jump starter according to claim 30, wherein a pin 9 of the BOOST chip is connected with GND; a pin 6 of the BOOST chip is connected with a capacitor C28; a pin 5 of the BOOST chip is connected with a resistor R63, a resistor R59 and a resistor R67; the other end of the resistor R59 is connected with a capacitor C29; and the other ends of the resistor C29 and the resistor R67 are connected with a capacitor C32.

32. The lithium battery emergency jump starter according to claim 31, wherein a pin 6 of the BUCK chip is connected with GND; a pin 4 of the BUCK chip is connected with a capacitor C3; the other end of the capacitor C3 is connected with GND; the pin 2 of the BUCK chip is connected with a resistor R4; the other end of the resistor R4 is connected with a resistor R80; the other end of the resistor R80 is connected with an emitter of the triode Q15 and a resistor R80; and the other end of the resistor R80 is connected with the base of the triode Q15.

33. The lithium battery emergency jump starter according to claim 32, wherein a pin 1 of the BUCK chip is connected with an inductor L1; the other end of the inductor L1 is connected with a diode D1 and a rectifier triode M4; a pin 4 of the rectifier triode M4 is connected with a pin 5 of the BUCK chip; a pin 1, a pin 2 and a pin 3 of the rectifier triode M4 are connected with a capacitor C1; the other end of the capacitor C1 is connected with an output end of the diode D1; the output end of the diode D1 is connected with a capacitor C40, a resistor R13 and a triode Q11; the other ends of the capacitor C40 and the resistor R13 and a base of the triode Q11 are connected with a resistor R72 and a triode Q13; an emitter of the triode Q13 is connected with GND; a base of the triode Q13 is connected with a resistor R74 and a resistor R73; and the other end of the resistor R73 is connected with VIN.

34. The lithium battery emergency jump starter according to claim 33, wherein the pin 2 of the BUCK chip is connected with a resistor R9, the other end of the resistor R9 is connected with a diode D3, and an input end of the diode D3 is connected with DICR.

35. The lithium battery emergency jump starter according to claim 33, wherein the lithium battery emergency jump starter can recognize a disconnected state of the pin when a male connector is not inserted, to complete the plug and pull detection of the male connector of the TYPE-C jack, thereby avoiding the waste of battery energy caused by a reactive working state of a product control circuit during empty plugging of a USB without load.

36. The lithium battery emergency jump starter according to claim 7, wherein the lithium battery emergency jump starter is connected with a delayer, and the delayer is communicated with a wire in which the clamping head is located, and communicated with the battery balance management module; the delayer is used for recognizing the voltage of an electrified vehicle; when the clamping head is correctly connected with outside, the delayer releases large-current output after delay, and when the clamping head is wrongly connected with the outside, the lithium battery emergency jump starter does not work.

37. The lithium battery emergency jump starter according to claim 36, wherein the delayer comprises a chip, a triode and a resistor.

38. The lithium battery emergency jump starter according to claim 36, wherein when the delayer works in delay, a buzzer on a control board generates a prompt tone.

39. The lithium battery emergency jump starter according to claim 36, wherein once a delay deadline of the delayer passes, the relay is automatically closed, and large current is outputted; and after the clamping head is disconnected from the outside, an output function of the relay is automatically closed.

40. The lithium battery emergency jump starter according to claim 39, wherein when the delayer works, a starting state of the externally connected vehicle is detected in real time; when the voltage generated after the externally connected vehicle is started is greater than the internal voltage of the lithium battery emergency jump starter, the delayer feeds back information to the battery balance management module, and the battery balance management module controls the relay to disconnect the relay to stop large-flow output.

41. The lithium battery emergency jump starter according to claim 40, wherein the battery balance management module controls the opening and closing mode of the relay by intermittent opening and closing.
